(19) United States
(12) Patent Application Publication
(10) Pub. No.: US 2012/0299116 A1
(43) Pub. Date: Nov. 29, 2012

(54) DISPLAY PANEL AND METHOD OF MANUFACTURING THE SAME

(75) Inventors: Takayuki TAKEUCHI, Osaka (JP); Seiji NISHIYAMA, Osaka (JP)

(73) Assignee: PANASONIC CORPORATION, Osaka (JP)

(21) Appl. No.: 13/292,546

(22) Filed: Nov. 9, 2011

Related U.S. Application Data
(63) Continuation of application No. PCT/JP2011/002956, filed on May 26, 2011.

(51) Int. Cl. H01L 27/105; H01L 21/66; H01L 33/08

(52) U.S. Cl. 257/390; 438/34; 438/14; 257/E27.081; 257/E33.053; 257/E21.529

(57) ABSTRACT

A display panel, in which a plurality of drive units in a transistor array substrate include a faulty drive unit, and a plurality of pixel electrodes include a first pixel electrode corresponding to the faulty drive unit and a second drive unit corresponding to a non-faulty drive unit. A portion of the second pixel electrode is embedded in the corresponding contact hole, and is in contact with a power supply pad of the non-faulty drive unit, so that the second pixel electrode is electrically connected to the non-faulty drive unit. An insulator is inserted between the first pixel electrode and a power supply pad of the faulty drive unit, so that the first pixel electrode is electrically insulated from the faulty drive unit.

### CROSS REFERENCE TO RELATED APPLICATION

This is a continuation application of PCT Application No. PCT/JP2011/002956 filed May 26, 2011, designating the United States of America, the disclosure of which, including the specification, drawings and claims, is incorporated herein by reference in its entirety.

### TECHNICAL FIELD

The present invention relates to an active-matrix display panel and a method of manufacturing the same.

### BACKGROUND ART

In a display panel of this type, a drive unit is provided for each pixel electrode arranged in a matrix. Each drive unit includes a thin-film transistor element. It is ideal that all the thin-film transistor elements of the drive units operate properly. In reality, however, there are cases where some of the thin-film transistor elements are faulty due to poor pressure endurance of gate insulation films, breaking of wiring lines, or the likes. When a pixel electrode is supplied with power by a drive unit including a faulty thin-film transistor element, a dark dot or a bright dot could occur in the display panel. In particular, any display panel having a bright dot should be unacceptable in terms of product quality standards. For this reason, Patent Literature 1 discloses a technology to prevent the faulty drive unit and the pixel electrode corresponding to the faulty drive unit from electrically connecting with each other, by cutting some of the wiring lines of the faulty thin-film transistor element, using laser. This technology changes the bright dot corresponding to the faulty drive unit in the display panel to a dark dot, and thus prevents the occurrence of bright dots in the display panel.

### CITATION LIST

### Patent Literature

[Patent Literature 1] Japanese Patent Application Publication No. 63-276032

### SUMMARY OF INVENTION

### Technical Problem

However, cutting wiring lines with laser is problematic since shards of the wiring lines scatters, which results in the increases of particles. The increase of particles could lead to short circuit between the source and the drain of thin-film transistor elements.

In addition, in order to cut off some wiring lines, it is generally necessary to provide a thin portion in each wiring line to facilitate the cutting. Also, it is necessary to design a layout in which electrodes and the likes are not located under such portions. In other words, the adoption of the technology of cutting off some wiring lines makes it necessary to design the layout under the restrictions.

As a result, there are cases where the thin-film transistor elements should be reduced in size. This leads to degradation of the capability of the thin-film transistor elements, and the drive units may have the following problems, for example: 1) the drive units fail to apply a desired current to the pixels; 2) the drive units take a longer time to charge capacitors; and 3) it will be impossible to place a transistor for compensation circuitry. Such problems degrade the performance of the display panel. For example, the luminance of the display panel, which is one aspect of the performance, could be degraded.

The present invention aims to provide a display panel that suppresses the increase of particles and frees the thin-film transistor elements from restrictions in terms of the arrangement thereof.

### Solution to Problem

To solve the problem, one aspect of the present invention provides a display panel comprising: a transistor array substrate having a plurality of drive units arranged in a matrix, each drive unit including a thin-film transistor element; an interlayer insulation film formed on the transistor array substrate and having contact holes, the contact holes corresponding one-to-one to the drive units; and a plurality of pixel electrodes arranged on the interlayer insulation film in a matrix, the pixel electrodes corresponding one-to-one to the drive units, wherein the drive units include a faulty drive unit and a non-faulty drive unit, the pixel electrodes include a first pixel electrode and a second pixel electrode, the first pixel electrode corresponding to the faulty drive unit, and the second pixel electrode corresponding to the non-faulty drive unit, a portion of the second pixel electrode is embedded in the contact hole corresponding thereto, and is in contact with a power supply pad of the non-faulty drive unit so that the second pixel electrode is electrically connected to the non-faulty drive unit, and an insulator is inserted between the first pixel electrode and a power supply pad of the faulty drive unit so that the first pixel electrode is electrically insulated from the faulty drive unit.

### Advantageous Effects of Invention

In the display panel pertaining to one aspect of the present invention, an insulator is inserted between the first pixel electrode and a power supply pad of the faulty drive unit, so that the first pixel electrode is electrically insulated from the faulty drive unit. Since the insulation is not realized by cutting wiring lines, there is no increase in the number of particles, and no restriction is imposed in terms of the layout.

### BRIEF DESCRIPTION OF DRAWINGS

FIG. 1A is a block diagram showing an electrical structure of a display device 100 pertaining to Embodiment 1 of the present invention, and FIG. 1B is a diagram showing the structure of a pixel circuit of a display panel 105 and connections with peripheral circuits.

FIG. 2 is a schematic plan view showing an arrangement of gate lines 200, data lines 201, power lines 202 and drive units 209 included in the display panel 105.

FIG. 3 is a schematic plan view showing an arrangement of the pixel electrodes 205 included in the display panel 105.

FIG. 4A is a partial cross-sectional view (cross-section along A-A′ in FIG. 2) schematically showing the structure of the display panel 105, and FIG. 4B is a partial cross-sectional view (cross-section along B-B′ in FIG. 2) schematically showing the structure of the display panel 105.

FIG. 5 is a diagram showing steps for manufacturing the display panel 105.

FIGS. 6A through 6E constitute a process chart showing an example of an interlayer insulation film formation step, an interlayer insulation film hole filling step, and a pixel electrode formation step.

FIG. 7 is a partial cross-sectional view schematically showing primary components of the display panel 105.

FIG. 8 is a partial cross-sectional view schematically showing the structure of a display panel pertaining to Modification 1.

FIG. 9 is a schematic plan view showing an arrangement of gate lines 200a, power lines 202a, drive units 501 and pixel electrodes 601 included in a display panel pertaining to Modification 2.

FIG. 10A is a partial cross-sectional view (cross-section along C-C′ in FIG. 9) schematically showing the structure of the display panel pertaining to Modification 2, and FIG. 10B is a partial cross-sectional view (cross-section along D-D′ in FIG. 9) schematically showing the structure of the display panel pertaining to Modification 2.

FIG. 11 shows an external view of the display device 100.

### DESCRIPTION OF EMBODIMENTS

### <Aspects>

One aspect of the present invention is a display panel comprising: a transistor array substrate having a plurality of drive units arranged in a matrix, each drive unit including a thin-film transistor element; an interlayer insulation film formed on the transistor array substrate and having contact holes, the contact holes corresponding one-to-one to the drive units; and a plurality of pixel electrodes arranged on the interlayer insulation film in a matrix, the pixel electrodes corresponding one-to-one to the drive units, wherein the drive units include a faulty drive unit and a non-faulty drive unit, the pixel electrodes include a first pixel electrode and a second pixel electrode, the first pixel electrode corresponding to the faulty drive unit, and the second pixel electrode corresponding to the non-faulty drive unit, a portion of the second pixel electrode is embedded in the contact hole corresponding thereto, and is in contact with a power supply pad of the non-faulty drive unit so that the second pixel electrode is electrically connected to the non-faulty drive unit, and an insulator is inserted between the first pixel electrode and a power supply pad of the faulty drive unit so that the first pixel electrode is electrically insulated from the faulty drive unit.

In the display panel pertaining to one aspect of the present invention, an insulator is inserted between the first pixel electrode and a power supply pad of the faulty drive unit, so that the first pixel electrode is electrically insulated from the faulty drive unit. Since the insulation is not realized by cutting wiring lines, there is no increase in the number of particles, and no restriction is imposed in terms of the layout.

In this aspect, the contact hole corresponding to the faulty drive unit may be partially filled with the insulator, and at least the bottom of the contact hole may be coated with the insulator.

In this aspect, the insulator may be made of acrylic resin.

In this aspect, the interlayer insulation film may include: a passivation film formed on the transistor array substrate; and a planarizing film formed on the passivation film.

In this aspect, the display panel is an electroluminescent display panel.

In this aspect, the display panel may be an organic electroluminescent display panel.

Another aspect of the present invention is a method of manufacturing a display panel, comprising: a preparation step of preparing a substrate; a transistor array substrate formation step of forming a transistor array substrate by arranging drive units on the substrate in a matrix, each drive unit including a thin-film transistor element; an interlayer insulation film formation step of forming an interlayer insulation film on the transistor array substrate, the interlayer insulation film having contact holes, the contact holes corresponding one-to-one to the drive units; and a pixel electrode formation step of arranging a plurality of pixel electrodes on the interlayer insulation film in a matrix, the pixel electrodes corresponding one-to-one to the drive units, wherein the drive units include a faulty drive unit and a non-faulty drive unit, the pixel electrodes include a first pixel electrode and a second pixel electrode, the first pixel electrode corresponding to the faulty drive unit, and the second pixel electrode corresponding to the non-faulty drive unit, and in the pixel electrode formation step, the second pixel electrode is formed such that a portion thereof is embedded in the corresponding contact hole, wherein the method further comprises: an insulator formation step of forming an insulator within the contact hole between the faulty drive unit and the first pixel electrode, the insulator formation step being performed between the interlayer insulation film formation step and the pixel electrode formation step, wherein the second pixel electrode is electrically connected to the non-faulty drive unit by bringing the portion of the second pixel electrode in contact with a power supply pad of the non-faulty drive unit, and the first pixel electrode is electrically insulated from the faulty drive unit by inserting the insulator between the first pixel electrode and a power supply pad of the faulty drive unit.

According to the method of manufacturing a display panel pertaining to this aspect of the present invention, since the first pixel electrode is electrically insulated from the faulty drive unit by forming the insulator within the contact hole between the faulty drive unit and the first pixel electrode, there is no increase in the number of particles, and no restriction is imposed in terms of the layout.

In the insulator formation step of this aspect, the contact hole corresponding to the faulty drive unit may be partially filled with the insulator, and at least the bottom of the contact hole may be coated with the insulator.

According to the method of manufacturing a display panel pertaining to this aspect, since the contact hole is not fully filled with the insulator, the insulating material is prevented from overflowing from the contact hole.

In the insulator formation step of this aspect, the insulator may be formed by using acrylic resin.

In this aspect, the interlayer insulation film formation step may include: a passivation film formation sub-step of forming a passivation film on the transistor array substrate; and a planarizing film formation sub-step of forming a planarizing film on the passivation film.

Another aspect of the present invention is a method of manufacturing a display panel, comprising: a preparation step of preparing a substrate; a transistor array substrate formation step of forming a transistor array substrate by arranging drive units on the substrate in a matrix, each drive unit including a thin-film transistor element; a detection step of detecting, from among the drive units arranged on the substrate, a faulty drive unit including a faulty thin-film transistor element; a positional information acquiring step of acquiring positional information of the faulty drive unit detected in the detection step; an interlayer insulation film formation step of forming an interlayer insulation film on the transistor array substrate, the interlayer insulation film having contact holes, the contact holes corresponding one-to-one to the drive units; and a pixel electrode formation step of arranging a plurality of pixel electrodes on the interlayer insulation film in a matrix, the pixel electrodes corresponding one-to-one to the drive units, wherein the drive units include the faulty drive unit and a non-faulty drive unit, the pixel electrodes include a first pixel electrode and a second pixel electrode, the first pixel electrode corresponding to the faulty drive unit, and the second pixel electrode corresponding to the non-faulty drive unit, and in the pixel electrode formation step, the second pixel electrode is formed such that a portion thereof is embedded in the corresponding contact hole, wherein the method further comprises: an insulator formation step of forming an insulator within the contact hole corresponding to the positional information, the insulator formation step being performed between the interlayer insulation film formation step and the pixel electrode formation step, wherein the second pixel electrode is electrically connected to the non-faulty drive unit by bringing the portion of the second pixel electrode into contact with a power supply pad of the non-faulty drive unit, and the first pixel electrode is electrically insulated from the faulty drive unit by inserting the insulator between the first pixel electrode and a power supply pad of the faulty drive unit.

### Embodiment 1

### Schematic Block Diagram of Display Device 100

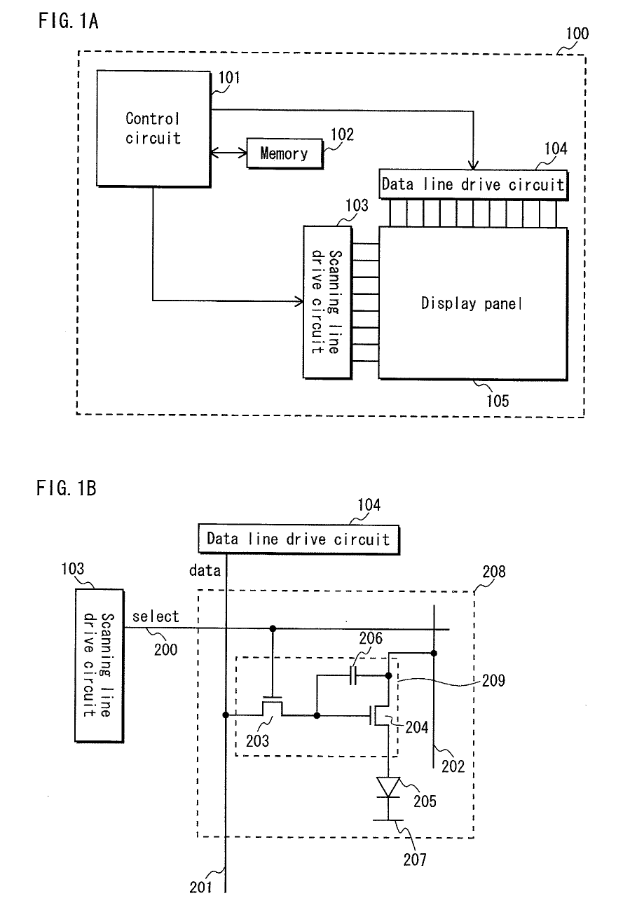

FIG. 1A is a block diagram showing an electrical structure of a display device 100 including a display panel 105 pertaining to Embodiment 1 of the present invention. As shown in FIG. 1A, the display device 100 includes a control circuit 101, a memory 102, a scanning line drive circuit 103, a data line drive circuit 104, and a display panel 105 in which pixel circuits are arranged in a matrix. The display panel 105 is an electroluminescent (hereinafter, “EL”) display panel, for example, and may be an organic EL display panel. Also, the display panel 105 may be a liquid crystal display panel.

FIG. 1B is a diagram showing the structure of a pixel circuit of the display panel 105 and connections with peripheral circuits. As shown in FIG. 1B, a pixel circuit 208 includes a gate line 200, a data line 201, a power line 202, a switching transistor 203, a drive transistor 204, a pixel electrode 205, a capacitor 206, and a common electrode 207. The switching transistor 203 and the drive transistor 204 are thin-film transistor elements. A light-emitting layer composed of a plurality of functional sub-layers, or a liquid crystal is formed between the pixel electrode 205 and the common electrode 207.

The peripheral circuits include the scanning line drive circuit 103 and the data line drive circuit 104. The switching transistor 203, the drive transistor 204 and the capacitor 206 constitute a drive unit 209.

When the display panel 105 is an EL display panel, signal voltage provided from the data line drive circuit 104 is applied to a gate terminal of the drive transistor 204 via the switching transistor 203. The drive transistor 204 causes current to flow between the source and drain terminals according to the data voltage applied. The current flowing to the pixel electrode 205 results in a luminance corresponding to the current.

When the display panel 105 is a liquid crystal display panel, current flows between the source and drain terminals of the switching transistor 203 due to the voltage applied to the gate line 200, and the voltage applied to the data line 201 is supplied to the pixel electrode 205.

### —Layout—

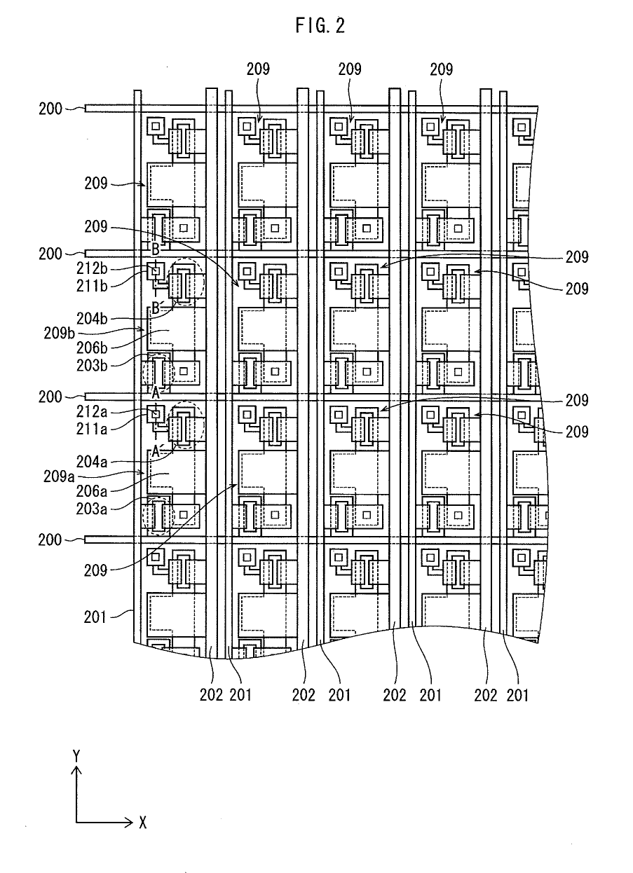

Next, description is provided for the arrangement of the gate lines 200, the data lines 201, the power lines 202 and the drive units 209 included in the display panel 105. FIG. 2 is a schematic plan view showing the arrangement of the gate lines 200, the data lines 201, the power lines 202 and the drive units 209 included in the display panel 105.

As shown in FIG. 2, the drive units 209 are arranged in a matrix. Some of the drive units 209 are assumed to be faulty, and the others are assumed to be not faulty (and operate normally). The term “faulty drive unit” means a drive unit that includes a thin-film transistor that is always on or a thin-film transistor that is always off. The following explanation focuses on the two drive units (a drive unit 209a and a drive unit 209b) that are adjacent in the column (Y-axis) direction. In FIG. 2, the drive unit 209a is a drive unit that is not faulty, and the drive unit 209b is a drive unit that is faulty.

A gate line 200 is provided along one side of each row constituted of a series of drive units arranged in the row direction. A data line 201 is provided along one side of each column constituted of a series of drive units arranged in the column direction, and a power line 202 is provided along the other side.

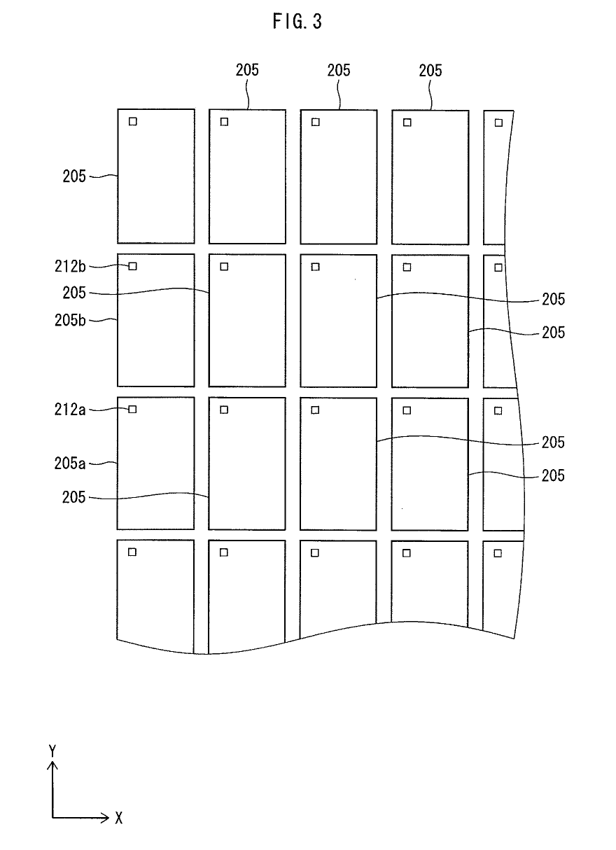

FIG. 3 is a schematic plan view showing an arrangement of the pixel electrodes 205 included in the display panel 105. As shown in FIG. 3, the pixel electrodes 205 are arranged in a matrix. The pixel electrodes 205 are provided in one-to-one correspondence with the drive units 209 shown in FIG. 2. The pixel electrodes 205 therefore include pixel electrodes (second pixel electrodes) that correspond one-to-one to drive units that are not faulty, and pixel electrodes (first pixel electrodes) that correspond one-to-one to drive units that are faulty. In FIG. 3, the pixel electrode 205a represents a pixel electrode corresponding to the drive unit 209a, and the pixel electrode 205b represents a pixel electrode corresponding to the drive unit 209b.

### —Cross-Sectional View—

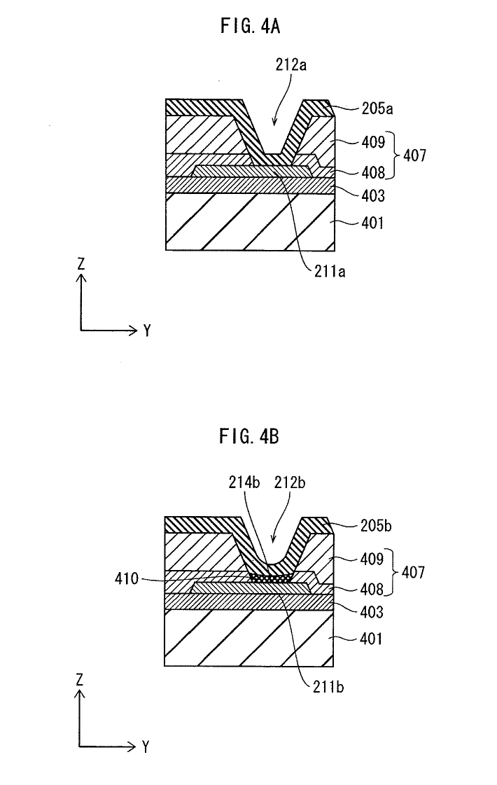

FIG. 4A is a partial cross-sectional view (cross-section along A-A′ in FIG. 2) schematically showing the structure of the display panel 105. As shown in FIG. 4A, a gate insulation film 403 is formed on a substrate 401, and a power supply pad 211a is formed on the gate insulation film 403. Furthermore, an interlayer insulation film 407 is formed to coat the power supply pad 211a. The interlayer insulation film 407 has a two-layer structure, for example, and is composed of a passivation film 408 and a planarizing film 409. A portion of the interlayer insulation film 407, which has contact with the power supply pad 211a, is provided with a contact hole 212a. The pixel electrode 205a is formed along the contact hole 212a so as to have contact with the power supply pad 211a.

As described above, a portion of the pixel electrode 205a enters into the contact hole 212a and the pixel electrode 205a has direct contact with the power supply pad 211a.

Due to this structure, the drive unit 209a is electrically connected with the pixel electrode 205a, and the drive unit 209a supplies power to the pixel electrode 205a.

FIG. 4B is a partial cross-sectional view (cross-section along B-B′ in FIG. 2) schematically showing the structure of the display panel 105. As shown in FIG. 4B, a gate insulation film 403 is formed on a substrate 401, and a power supply pad 211b is formed on the gate insulation film 403. Furthermore, an interlayer insulation film 407 is formed to coat the power supply pad 211b. The interlayer insulation film 407 has a two-layer structure, for example, and is composed of a passivation film 408 and a planarizing film 409. A portion of the interlayer insulation film 407, which has contact with the power supply pad 211b, is provided with a contact hole 212b. The structure in terms of the points mentioned above is the same as the structure shown in FIG. 4A. In FIG. 4B, however, an insulator 410 is formed within the contact hole 212b. The pixel electrode 205b is formed on the interlayer insulation film 407 and the insulator 410, along the contact hole 212b.

The insulator 410 is made of polyimide resin or acrylic resin, for example. The insulator 410 is formed so as to coat at least a bottom 214b of the contact hole 212b. The insulator 410, however, needs to have a sufficient thickness to insulate the pixel electrode 205b from the power supply pad 211b.

As described above, the insulator 410 is disposed between the portion of the pixel electrode 205b corresponding to the contact hole 212b (in this example, the portion of the pixel electrode 205b entering into the contact hole 212b) and the power supply pad 211b. The pixel electrode 205b and the drive unit 209b are therefore prevented from electrically connecting with each other. Since the pixel electrode 205b and the drive unit 209b are not electrically connected, the drive unit 209b does not supply power to the pixel electrode 205b. Consequently, a pixel in the display panel 105 corresponding to the pixel electrode 205b will be a dark dot. Hence, even when a faulty thin-film transistor element exists in the display panel 105, no bright dot occurs in the display panel 105.

In addition, in the structure described above, the pixel electrode 205b and the drive unit 209b are electrically insulated from each other by forming the insulator 410 within the contact hole 212b, instead of by cutting off a wiring line of the thin-film transistor element of the drive unit 209b. Since no wiring line is cut off, naturally the particles do not increase due to the cutting of wiring lines, and the thin-film transistor elements are free from restrictions in terms of the arrangement thereof.

Although the structures of the drive unit 209a and the pixel electrode 205a are explained above as examples of non-faulty drive units and pixel electrodes corresponding thereto, other non-faulty drive units and their corresponding pixel electrodes have the same structures.

Similarly, although the structures of the drive unit 209b and the pixel electrode 205b are explained above as examples of faulty drive units and pixel electrodes corresponding thereto, other faulty drive units and their corresponding pixel electrodes have the same structures. That is, the insulators are inserted between the pixel electrodes corresponding to the other faulty drive units and the power supply pads of the faulty drive units.

### —Manufacturing Procedures—

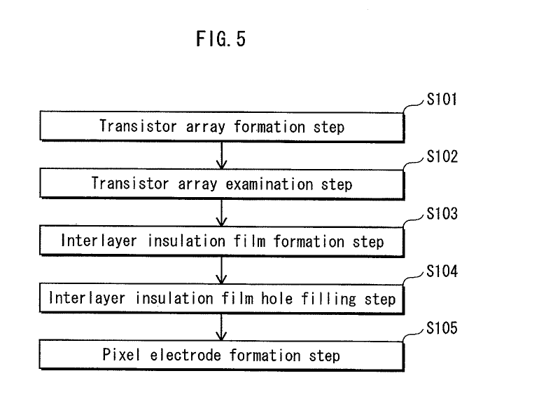

The following explains the manufacturing procedures for the display panel 105. In particular, the step for forming a transistor array to the step for forming pixel electrodes are explained here. FIG. 5 is a diagram showing the steps for manufacturing the display panel 105.

First, in the transistor array formation in Step S101, a transistor array substrate is formed by forming drive units in a matrix on a substrate.

In the transistor array examination in Step S102, the drive units formed in a matrix are examined to specify faulty thin-film transistor elements. In particular, a defect inspection device sets the addresses of the thin-film transistor elements of the drive units formed in a matrix. Next, electrical potential is applied to the gate lines, the data lines and the power lines, and a potential is measured at each address by using a contactless electrometer. If the potential obtained by the measurement is a normal value, it is determined that the thin-film transistor element corresponding to the address is not faulty. On the other hand, if the potential obtained by the measurement is not a normal value, it is determined that the thin-film transistor element corresponding to the address is faulty. Note that there are two types of faulty elements. One is a thin-film transistor element that is always on. Such a state is referred to as a short-circuit state. The other is a thin-film transistor element that is always off. Such a state is referred to as an off state. The defect inspection device determines in which state a faulty thin-film transistor is, by adjusting the potential to be applied to each signal line. That is, the defect inspection device determines, for each thin-film transistor element, whether the element is normal, or in the short-circuit state, or in the off state.

In the interlayer insulation film formation in Step S103, an interlayer insulation film is formed on the transistor array substrate. The interlayer insulation film has a structure in which a contact hole is provided in portions corresponding to the power supply pad of each drive unit.

In interlayer insulation film hole filling in Step S104, an insulator is formed in the contact hole corresponding to the drive unit including the thin-film transistor element that has been determined as faulty.

When the faulty thin-film transistor element is in the short-circuit state, it is necessary to avoid supplying power to the pixel electrode. On the other hand, when the faulty thin-film transistor element is in the off state, it is not necessary to avoid supplying power to the pixel electrode. This is because when the thin-film transistor element is in the off state, the pixel corresponding thereto is a dark dot, and is unnoticeable even when the pixels around it emit light.

On the other hand, when the faulty thin-film transistor element is in the on state, the pixel corresponding thereto is a bright dot, and is noticeable for the user when the pixels around it are unlighted (e.g. when no image is displayed on the display panel or in the case of raster display with a low luminance), even if there is only one bright dot. Therefore, a display panel having even only one bright dot is considered as a faulty panel. For this reason, it is necessary to form an insulator the contact hole corresponding to the drive unit including the thin-film transistor element that is in the on state.

In the pixel electrode formation in Step S105, pixel electrodes are formed in matrix so as to correspond one-to-one to the drive units. In this embodiment, each of the pixel electrodes is formed such that a portion thereof enters into the corresponding contact hole.

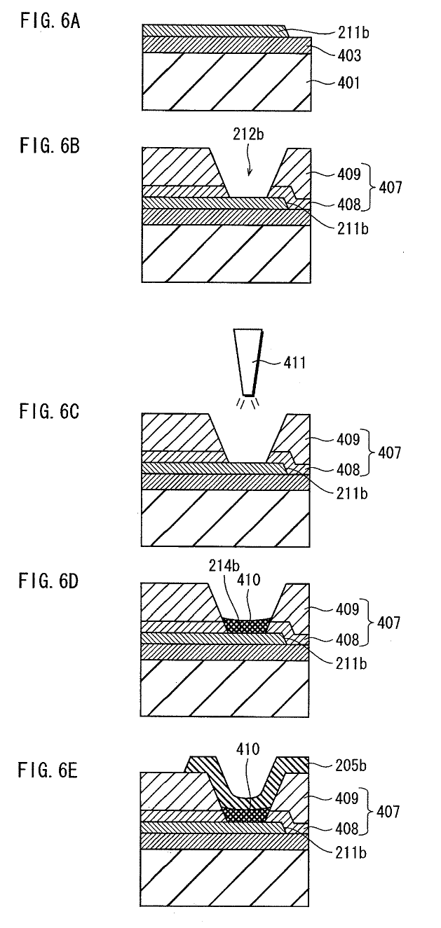

The following explains in detail an interlayer insulation film formation step, an interlayer insulation film hole filling step and a pixel electrode formation step, with reference to FIGS. 6A thorough 6E. FIGS. 6A through 6E constitute a process chart showing an example of an interlayer insulation film formation step, an interlayer insulation film hole filling step, and a pixel electrode formation step.

FIG. 6A shows that the gate insulation film 403 has been formed on the substrate 401, and the power supply pad 211b has been formed on the gate insulation film 403.

After that, an insulating material film, which is made of insulating material and to be processed to form the interlayer insulation film, is formed on the power supply pad 212b. Here, the insulating material film may have a two-layer structure composed of a layer to be processed to form a passivation film and a layer to be processed to form a planarizing film. The insulating material film may be formed by CVD (Chemical Vapor Deposition) or embrocation.

Next, a contact hole is formed in a portion of each of the areas corresponding to the drive units. Specifically, after applying a resist film onto the insulating material film, a mask with apertures having a predetermined shape is layered thereon, and the resist film is exposed to light from above the mask. Then, the remaining resist film is washed off by developer (e.g. TMAH (Tetra methyl ammonium hydroxide) aqueous solution). Subsequently, portions of the insulating material film in the apertures are removed by dry etching, and then the resist film is stripped off. Thus the patterning of the insulating material film completes.

When a photosensitive application film is used as the insulating material film, the patterning can be performed directly with developer, and it is unnecessary to strip off the resist film or perform dry etching.

The insulating material film 407 after the patterning has a contact hole 212b in the portion above the power supply pad 211b (FIG. 6B).

After that, as shown in FIG. 6C, an insulating material that is the same as the material of the planarizing film is discharged with a dispenser 411 onto a portion of the power supply pad 211b where is exposed from the insulating material film 407 (i.e. the portion within the contact hole 212b). As shown in FIG. 6D, the insulating material is formed so as to coat at least the bottom 214b of the contact hole 212b. With this structure, the shape of the pixel electrodes will be constant in the subsequent procedures, regardless of whether the insulating material is formed in the contact hole or not. The advantageous effect of such a constant shape is described next.

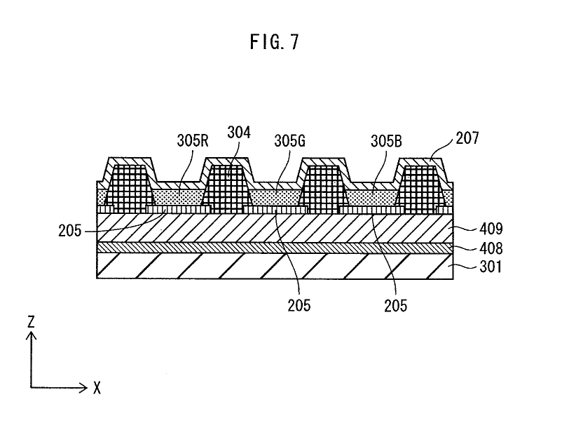

When the display panel 105 is an EL display panel, an EL substrate (See FIG. 7) and a color filter substrate are attached together, with a sealing resin (i.e., the space between the substrates is filled with the sealing resin). The substrates can be attached in a preferable state when the joint areas of the substrates are flat. By forming the insulating material to coat a portion of the contact hole 212b, the joint area on the EL substrate, where is to be attached to the color filter substrate, is prevented from being provided with a protrusion attributed to the insulating material. This realizes a preferable attachment of the substrates.

Moreover, when the insulating material is discharged to fill the contact hole 212b, there is a risk that the insulating material overflows onto the area surrounding the contact hole 212b. Such an overflow deteriorates the flatness ensured by the use of the planarizing film. Such a problematic situation can be avoided by forming the insulating material to coat only a portion of the contact hole 212b.

Returning to the explanation of the manufacturing procedures, after the insulating material is discharged into the contact hole, a baking step is performed. Thus, the interlayer insulation film 407, which includes the passivation film 408 and the planarizing film 409, and the insulator 410 are completed. In this way, the increase in the number of steps due to the baking step can be avoided by using the same material for forming the planarizing film 409 and the insulator 410.

After that, the pixel electrode 205b is formed on the planarizing film 409 and the insulator 410, along the contact hole. As shown in FIG. 6E, the pixel electrode 205b is formed such that a portion thereof exists within the contact hole 212b even after the insulator 410 is formed (i.e. the pixel electrode 205b is concave).

Also, since the pixel electrode 205b and the drive unit 209b are prevented from electrically connecting with each other by forming the insulator 410, it is unnecessary to change the arrangement of the thin-film transistor element and the wiring lines. Therefore, the existing mask can be used without any change. This is advantageous in terms of the cost.

This concludes the explanation of the interlayer insulation film formation step, the interlayer insulation film hole filling step, and the pixel electrode formation step.

In the embodiment described above, the planarizing film 409 and the insulator 410 are made of the same material, and both the planarizing material film and the insulating material are baked in a single baking step. However, as a matter of course, the baking step may be performed once after the insulating material film is patterned, and then performed again after the insulating material is added into the contact hole. If this is the case, it is preferable that the insulator is made of a material that requires a short baking time. For example, a polyimide resin with an initiator added may be used.

### —Structure of Display Panel 105—

In this section, the structure of an EL display panel as an example of the display panel 105 is explained.

FIG. 7 is a partial cross-sectional view schematically showing primary components of the display panel 105. As shown in FIG. 7, a passivation film 408 is formed on the transistor array substrate 301, and a planarizing film 409 is formed on the passivation film 408. Pixel electrodes (anodes) 205 are formed on the planarizing film 409. The pixel electrodes 205 are formed by patterning so as to be in a matrix composed of sub-pixels. Three sub-pixels that are adjacent in X axis direction constitute one pixel.

A bank 304 is formed between adjacent pixel electrodes 205. In each area defined by the banks 304, a light-emitting layer 305G, 305R or 305B, each having a predetermined color, is layered on the pixel electrode 205. The light-emitting layers 305R, 305G and 305B are organic light-emitting layers, for example. A common electrode (cathode) 207 is formed on the light-emitting layers 305R, 305G and 305B so as to extend across the area defined by the banks 304 and to be continuous with another common electrode on the adjacent light-emitting layer.

The following explains in detail the material of each component and so on in the case the display panel 105 is an EL display panel.

### —Structure of Each Component—

The transistor array substrate 301 includes a substrate and a plurality of drive units arranged on the substrate in a matrix.

The passivation film 408 is made of insulating material such as polyimide resin, silicone resin, etc.

The planarizing film 409 is made of insulating material such as polyimide resin, acrylic-based resin, etc.

The pixel electrode 205 is made of aluminum (Al) or an aluminum alloy. Alternatively, the pixel electrode 205 may be made of silver (Ag), an alloy of silver, palladium and copper, an alloy of silver, rubidium and gold, an alloy of molybdenum and chrome (MoCr), an alloy of nickel and chrome (NiCr), etc. When the display panel 105 is a top-emission display panel, it is preferable that the pixel electrode 205 is made of light-reflective material.

The banks 304 are made of organic material, such as resin, and are insulative. Examples of the organic material include acrylic resin, polyimide resin, and novolac-type phenolic resin. It is preferable that the banks 304 have organic solvent resistance. Furthermore, since the banks 304 are etched and baked in some cases, it is preferable that the banks be formed from highly resistant material that will not change in shape or quality during the etching and baking processes.

When the light-emitting layers 305R, 305G and 305B are organic light-emitting layers, examples of the material in the light-emitting layers include a fluorescent material such as an oxinoid compound, perylene compound, coumarin compound, azacoumarin compound, oxazole compound, oxadiazole compound, perinone compound, pyrrolo-pyrrole compound, naphthalene compound, anthracene compound, fluorene compound, fluoranthene compound, tetracene compound, pyrene compound, coronene compound, quinolone compound and azaquinolone compound, pyrazoline derivative and pyrazolone derivative, rhodamine compound, chrysene compound, phenanthrene compound, cyclopentadiene compound, stilbene compound, diphenylquinone compound, styryl compound, butadiene compound, dicyanomethylene pyran compound, dicyanomethylene thiopyran compound, fluorescein compound, pyrylium compound, thiapyrylium compound, selenapyrylium compound, telluropyrylium compound, aromatic aldadiene compound, oligophenylene compound, thioxanthene compound, cyanine compound, acridine compound, metal complex of a 8-hydroxyquinoline compound, metal complex of a 2-bipyridine compound, complex of a Schiff base and a group three metal, metal complex of oxine, rare earth metal complex, etc., as recited in Japanese Patent Application Publication No. H5-163488.

The common electrode (cathode) 207 is made of, for example, indium tin oxide (ITO), indium zinc oxide (IZO), etc. When the display panel 105 is a top-emission display panel, it is preferable that the pixel electrode 207 is made of light-reflective material.

Although the display panel pertaining to the present invention is described above based on Embodiment, the present invention should not be limited to Embodiment, as a matter of course. For example, the following modifications may be made.

### <Modification 1>

The following explains a modification example in which the structure of the insulator is altered.

### —Cross-Sectional View—

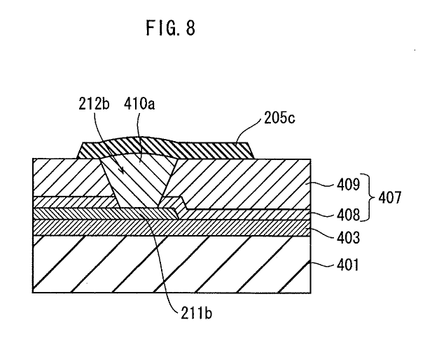

FIG. 8 is a partial cross-sectional view schematically showing the structure of a display panel pertaining to Modification 1. As shown in FIG. 8, a gate insulation film 403 is formed on a substrate 401, and a power supply pad 211b is formed on the gate insulation film 403. Furthermore, an interlayer insulation film 407 is formed to coat the power supply pad 211b. The interlayer insulation film 407 has a two-layer structure, for example, and is composed of a passivation film 408 and a planarizing film 409. A portion of the interlayer insulation film 407, which has contact with the power supply pad 211b, is provided with a contact hole 212b. The structure in terms of the points mentioned above is the same as the structure shown in FIG. 4B. The structure shown in FIG. 8 is different in that the insulator 410a is formed to completely fill the contact hole 212b. Therefore, no portion of the pixel electrode 205c exists within the contact hole 212b, and the pixel electrode 205c is formed to coat the insulator 410a which fills the contact hole 212b.

Even with such as structure, since no wiring line is cut off, naturally the particles do not increase due to the cutting of wiring lines, and the thin-film transistor elements are free from restrictions in terms of the arrangement thereof.

### <Modification 2>

The following explains a modification example in which the structure of each drive unit is altered. In this modification example, each drive unit includes a single thin-film transistor element.

### —Layout—

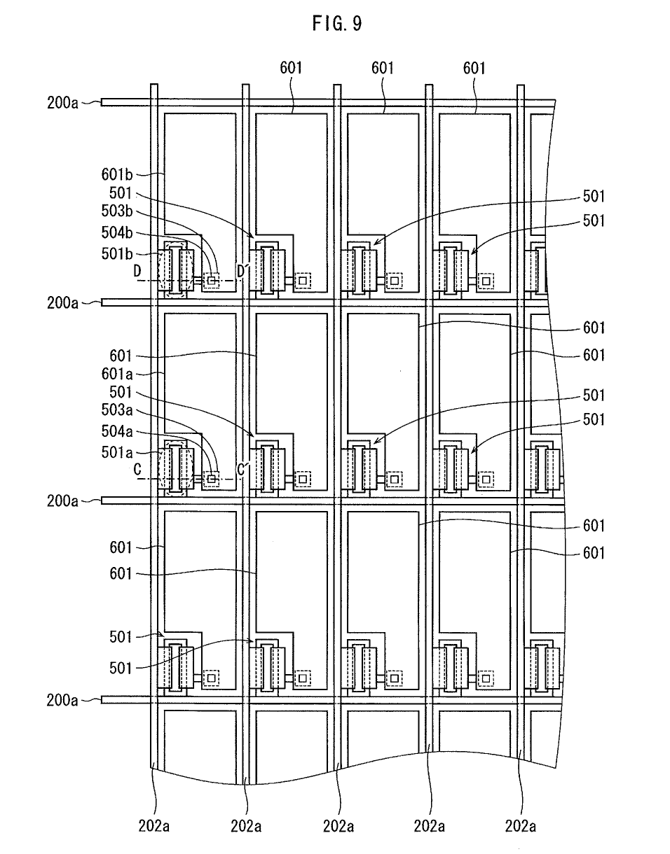

The following explains the arrangement of the gate lines 200a, the power lines 202a, the drive units 501 and the pixel electrodes 601 included in the display panel pertaining to Modification 2. FIG. 9 is a schematic plan view showing the arrangement of the gate lines 200a, the power lines 202a, the drive units 501 and the pixel electrodes 601 included in the display panel pertaining to Modification 2.

As shown in FIG. 9, the drive units 501 are arranged in a matrix. Some of the drive units 501 are assumed to be faulty, and the others are assumed to be not faulty. The pixel electrodes 601 are arranged in a matrix so as to correspond one-to-one to the drive units 501. The pixel electrodes 601 therefore include pixel electrodes (second pixel electrodes) that correspond one-to-one to drive units that are not faulty, and pixel electrodes (first pixel electrodes) that correspond one-to-one to drive units that are faulty. The following explanation focuses on the drive unit 501a, the drive unit 501b, the pixel electrode 601a and the pixel electrode 601b. In FIG. 9, the drive unit 501a represents a drive unit that is not faulty, and the drive unit 501b represents a drive unit that is faulty. Also, the pixel electrode 601a represents a pixel electrode corresponding to the drive unit 501a, and the pixel electrode 601b represents a pixel electrode corresponding to the drive unit 502b.

A gate line 200a is provided along one side of each row constituted of a series of drive units arranged in the row direction. A power line 202a is provided along one side of each column constituted of a series of drive units arranged in the column direction.

### —Cross-Sectional View—

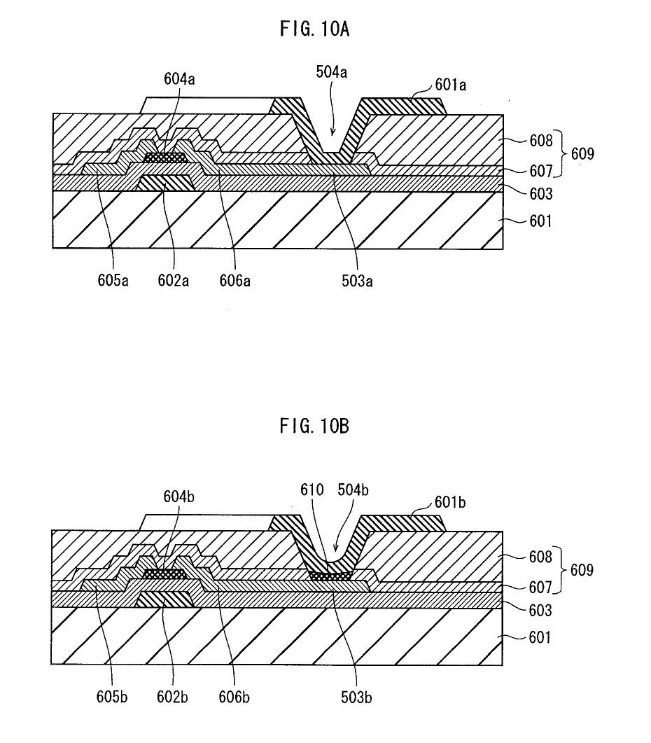

FIG. 10A is a partial cross-sectional view (C-C′ cross-section in FIG. 9) schematically showing the structure of a display panel pertaining to Modification 2. As shown in FIG. 10A, a gate electrode 602a is disposed on a substrate 601, and a gate insulation film 603 is disposed on the substrate 601 on which the gate electrode 602a has been disposed. A semiconductor layer 604a is formed on the portion of the gate insulation film 603 above the gate electrode 602a. In addition, SD electrode wiring lines 605a and 606a are disposed on the gate insulation film 603. Each of the SD electrode wiring lines 605a and 606a partially overlaps the semiconductor layer 604a. The SD electrode wiring lines 605a and 606a have a gap therebetween, and the gap is located above the semiconductor layer 604a. The SD electrode wiring lines 606a is connected to a power supply pad 503a.

An interlayer insulation film 609 is formed to coat the SD electrode wiring lines 605a and 606a and the power supply pad 503a. The interlayer insulation film 609 has a two-layer structure, for example, and is composed of a passivation film 607 and a planarizing film 608. A contact hole 504a is formed in the interlayer insulation film 609, and a pixel electrode 601a is formed along the contact hole 504a so as to have contact with the power supply pad 503a.

As described above, a portion of the pixel electrode 601a enters into the contact hole 504a and the pixel electrode 601a has direct contact with the power supply pad 503a.

Due to this structure, the drive unit 501a is electrically connected with the pixel electrode 601a, and the drive unit 501a supplies power to the pixel electrode 601a.

FIG. 10B is a partial cross-sectional view (D-D′ cross-section in FIG. 9) schematically showing the structure of a display panel pertaining to Modification 2. As shown in FIG. 10B, a gate electrode 602b is disposed on a substrate 601, and a gate insulation film 603 is disposed on the substrate 601 on which the gate electrode 602b has been disposed. A semiconductor layer 604b is formed on the portion of the gate insulation film 603 above the gate electrode 602b. In addition, SD electrode wiring lines 605b and 606b are disposed on the gate insulation film 603. Each of the SD electrode wiring lines 605b and 606b partially overlaps the semiconductor layer 604b. The SD electrode wiring lines 605b and 606b have a gap therebetween, and the gap is located above the semiconductor layer 604b. The SD electrode wiring lines 606b is connected to a power supply pad 503b.

An interlayer insulation film 609 is formed to coat the SD electrode wiring lines 605b and 606b and the power supply pad 503b. The interlayer insulation film 609 has a two-layer structure, for example, and is composed of a passivation film 607 and a planarizing film 608. A contact hole 504b is formed in the interlayer insulation film 609. The structure in terms of the points mentioned above is the same as the structure shown in FIG. 10A. In FIG. 10B, however, an insulator 610 is formed within the contact hole 504b. The pixel electrode 601b is formed on the interlayer insulation film 607 and the insulator 610, along the contact hole 504b.

The material and the thickness of the insulator 610, and the area where the insulator 610 is formed, are the same as the insulator 410 described in Embodiment 1 above.

As described above, the insulator 610 is disposed between the portion of the pixel electrode 601b corresponding to the contact hole 504b (in this example, the portion of the pixel electrode 601b entering into the contact hole 504b) and the power supply pad 503b. The pixel electrode 601b and the power supply pad 503b are therefore prevented from electrically connecting with each other. Since the pixel electrode 601b and the drive unit 501b are not electrically connected, the drive unit 501b does not supply power to the pixel electrode 601b. Consequently, a pixel in the display panel corresponding to the pixel electrode 601b will be a dark dot. Hence, even when a faulty thin-film transistor element exists in the display panel, no bright dot occurs in the display panel.

In addition, in the structure described above, the pixel electrode 601b and the drive unit 501b are electrically insulated from each other by forming the insulator 610 within the contact hole 504b, instead of by cutting off a wiring line of the thin-film transistor element of the drive unit 501b. Since no wiring line is cut off, naturally the particles do not increase due to the cutting of wiring lines, and the thin-film transistor elements are free from restrictions in terms of the arrangement thereof.

Note that other non-faulty drive units and the pixel electrodes corresponding to the non-faulty drive units, and other faulty drive units and the pixel electrodes corresponding to the faulty drive units have the same structure as described above. That is, the insulators are inserted between the pixel electrodes corresponding to the other faulty drive units and the power supply pads of the faulty drive units.

### <Other Modifications>

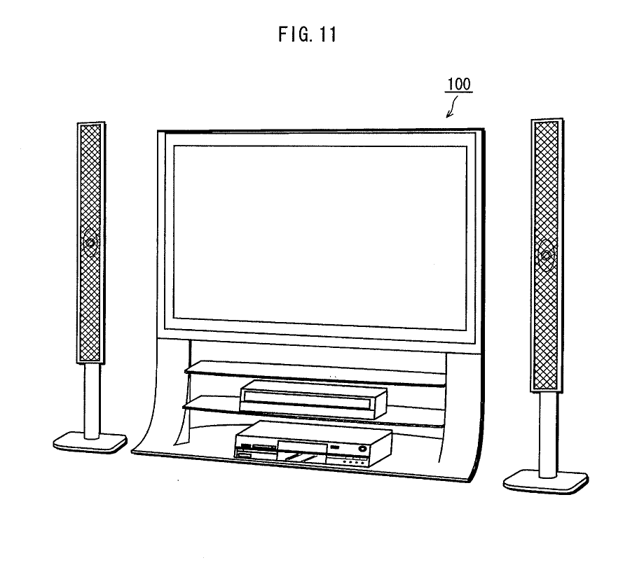

(1) When the display panel is an organic EL display panel, a hole-injection layer, a hole transporting layer, or a layer serving as both of the hole-injection layer and the hole transporting layer may be inserted between the pixel electrode and the organic light-emitting layer, according to needs. A hole-injection layer, a hole transporting layer, or a layer serving as both of the hole-injection layer and the hole transporting layer may be inserted between the common electrode and the organic light-emitting layer, according to needs.
(2) In this section, the structure of a liquid crystal display panel as an example of the display panel is explained. In a liquid crystal display panel, a passivation film is formed on a transistor array substrate, and a planarizing film is formed on the passivation film. A plurality of pixel electrodes are formed on the planarizing film. The structure in terms of the points mentioned above is the same as the EL display panel. The difference from the EL display panel is that a common electrode is disposed to face the pixel electrodes, and the gap between the pixel electrodes and the common electrode is filled with a liquid crystal.
(3) The pixel electrode 205a and the pixel electrode 205b may be connected via a connector made of conductive material. When each column in the display panel 105 has a different luminescent color, it is preferable that the pixel electrode 205b is connected to the pixel electrode 205a that is adjacent in the column direction. When the display panel 105 is for displaying one color, it is not necessary that the pixel electrode is connected to the adjacent pixel electrode in the column direction, and may be connected to the adjacent pixel electrode in the row direction. Similarly, the pixel electrode 601a and the pixel electrode 601b may be connected via a connector made of conductive material.
(4) Although it is described above that the insulating material is applied by using the dispenser 411, the insulator may be formed by applying, by ink jet or the like, insulating material that will be insulative after being dried, and then drying the material. Alternatively, resist material that does not require baking and will be hardened by irradiation with ultraviolet light may be used.
(5) Each of the pixel electrodes consists of the portion formed on the interlayer insulation film and the portion existing within the contact hole. These portions are not necessarily integrated in one piece, and they may be made of different materials.
(6) The external view of the display device 100 is as shown in FIG. 11, for example.

### INDUSTRIAL APPLICABILITY

The present invention is applicable to, for example, display devices for home use, public use and industrial use, television devices, and display panels for portable electronic devices.

### REFERENCE SIGNS LIST

100 display device
101 control circuit
102 memory
103 scanning line drive circuit
104 data line drive circuit
105 display panel
200 gate line
201 data line
202 power line
203 switching transistor
204 drive transistor
205, 205a, 205b pixel electrode
206 capacitor
207 common electrode
208 pixel circuit
209, 209a, 209b drive unit
211a, 211b power supply pad
212a, 212b contact hole
401 substrate
403 gate insulation film
407 interlayer insulation film
408 passivation film
409 planarizing film
410 insulator

1. A display panel comprising:
a transistor array substrate having a plurality of drive units arranged in a matrix, each drive unit including a thin-film transistor element;
an interlayer insulation film formed on the transistor array substrate and having contact holes, the contact holes corresponding one-to-one to the drive units; and
a plurality of pixel electrodes arranged on the interlayer insulation film in a matrix, the pixel electrodes corresponding one-to-one to the drive units, wherein
the drive units include a faulty drive unit and a non-faulty drive unit,
the pixel electrodes include a first pixel electrode and a second pixel electrode, the first pixel electrode corresponding to the faulty drive unit, and the second pixel electrode corresponding to the non-faulty drive unit,
a portion of the second pixel electrode is embedded in the contact hole corresponding thereto, and is in contact with a power supply pad of the non-faulty drive unit so that the second pixel electrode is electrically connected to the non-faulty drive unit, and
an insulator is inserted between the first pixel electrode and a power supply pad of the faulty drive unit so that the first pixel electrode is electrically insulated from the faulty drive unit.

2. The display panel of claim 1, wherein
the contact hole corresponding to the faulty drive unit is partially filled with the insulator, and at least the bottom of the contact hole is coated with the insulator.

3. The display panel of claim 1, wherein
the insulator is made of acrylic resin.

4. The display panel of claim 1, wherein
the interlayer insulation film includes:
a passivation film formed on the transistor array substrate; and
a planarizing film formed on the passivation film.

5. The display panel of claim 1, wherein
the display panel is an electroluminescent display panel.

6. The display panel of claim 5, wherein
the display panel is an organic electroluminescent display panel.

7. A method of manufacturing a display panel, comprising:
a preparation step of preparing a substrate;
a transistor array substrate formation step of forming a transistor array substrate by arranging drive units on the substrate in a matrix, each drive unit including a thin-film transistor element;
an interlayer insulation film formation step of forming an interlayer insulation film on the transistor array substrate, the interlayer insulation film having contact holes, the contact holes corresponding one-to-one to the drive units; and
a pixel electrode formation step of arranging a plurality of pixel electrodes on the interlayer insulation film in a matrix, the pixel electrodes corresponding one-to-one to the drive units, wherein
the drive units include a faulty drive unit and a non-faulty drive unit,
the pixel electrodes include a first pixel electrode and a second pixel electrode, the first pixel electrode corresponding to the faulty drive unit, and the second pixel electrode corresponding to the non-faulty drive unit, and
in the pixel electrode formation step, the second pixel electrode is formed such that a portion thereof is embedded in the corresponding contact hole, wherein
the method further comprises:
an insulator formation step of forming an insulator within the contact hole between the faulty drive unit and the first pixel electrode, the insulator formation step being performed between the interlayer insulation film formation step and the pixel electrode formation step, wherein
the second pixel electrode is electrically connected to the non-faulty drive unit by bringing the portion of the second pixel electrode in contact with a power supply pad of the non-faulty drive unit, and
the first pixel electrode is electrically insulated from the faulty drive unit by inserting the insulator between the first pixel electrode and a power supply pad of the faulty drive unit.

8. The method of claim 7, wherein
in the insulator formation step, the contact hole corresponding to the faulty drive unit is partially filled with the insulator, and at least the bottom of the contact hole is coated with the insulator.

9. The method of claim 7, wherein
in the insulator formation step, the insulator is formed by using acrylic resin.

10. The method of claim 7, wherein
the interlayer insulation film formation step includes:
a passivation film formation sub-step of forming a passivation film on the transistor array substrate; and
a planarizing film formation sub-step of forming a planarizing film on the passivation film.

11. The method of claim 7, wherein
the display panel is an electroluminescent display panel.

12. The method of claim 11, wherein
the display panel is an organic electroluminescent display panel.

13. A method of manufacturing a display panel, comprising:
a preparation step of preparing a substrate;
a transistor array substrate formation step of forming a transistor array substrate by arranging drive units on the substrate in a matrix, each drive unit including a thin-film transistor element;
a detection step of detecting, from among the drive units arranged on the substrate, a faulty drive unit including a faulty thin-film transistor element;
a positional information acquiring step of acquiring positional information of the faulty drive unit detected in the detection step;
an interlayer insulation film formation step of forming an interlayer insulation film on the transistor array substrate, the interlayer insulation film having contact holes, the contact holes corresponding one-to-one to the drive units; and
a pixel electrode formation step of arranging a plurality of pixel electrodes on the interlayer insulation film in a matrix, the pixel electrodes corresponding one-to-one to the drive units, wherein
the drive units include the faulty drive unit and a non-faulty drive unit,
the pixel electrodes include a first pixel electrode and a second pixel electrode, the first pixel electrode corresponding to the faulty drive unit, and the second pixel electrode corresponding to the non-faulty drive unit, and
in the pixel electrode formation step, the second pixel electrode is formed such that a portion thereof is embedded in the corresponding contact hole, wherein
the method further comprises:
an insulator formation step of forming an insulator within the contact hole corresponding to the positional information, the insulator formation step being performed between the interlayer insulation film formation step and the pixel electrode formation step, wherein
the second pixel electrode is electrically connected to the non-faulty drive unit by bringing the portion of the second pixel electrode into contact with a power supply pad of the non-faulty drive unit, and
the first pixel electrode is electrically insulated from the faulty drive unit by inserting the insulator between the first pixel electrode and a power supply pad of the faulty drive unit.

14. The method of claim 13, wherein
the contact hole corresponding to the faulty drive unit is partially filled with the insulator, and at least the bottom of the contact hole is coated with the insulator.

15. The method of claim 13, wherein
in the insulator formation step, the insulator is formed by using acrylic resin.
